(19) United States
(12) Patent Application Publication
(10) Pub. No.: US 2025/0222537 A1
(43) Pub. Date: Jul. 10, 2025

(54) SILICON COMPONENTS WELDED BY ELECTRON BEAM MELTING

(71) Applicant: SILFEX, INC., Eaton, OH (US)

(72) Inventors: Jihong CHEN, Cincinnati, OH (US); Rong WANG, Springboro, OH (US); Yi SONG, Eaton, OH (US); Vijay NITHIANANTHAN, Springboro, OH (US)

(21) Appl. No.: 18/853,459

(22) PCT Filed: Mar. 28, 2023
(86) PCT No.: PCT/US2023/016593

§ 371 Date: Oct. 2, 2024

Related U.S. Application Data
(60) Provisional application No. 63/327,068, filed on Apr. 4, 2022.

(51) Int. Cl. B23K 15/00; B23K 26/00; B23K 103/00

(52) U.S. Cl. CPC B23K 15/0053; B23K 15/002; B23K 15/0026; B23K 15/0033; B23K 15/0093; B23K 26/0006; B23K 2103/56

(57) ABSTRACT

A welded component for a substrate processing system includes a first component comprised of a first semiconductor material, a second component comprised of the first semiconductor material, a weld region defined between respective unwelded regions of the first component and the second component located on either side of the weld region, and a seam defined in the weld region between the first component and the second component. The weld region is comprised of the first semiconductor material of respective portions of the first component and the second component on either side of the seam that was melted and recrystallized to form the weld region.

### CROSS-REFERENCE TO RELATED APPLICATIONS

This application claims the benefit of U.S. Provisional Application No. 63/327,068, filed on Apr. 4, 2022. The entire disclosure of the above application is incorporated herein by reference.

### FIELD

The present disclosure relates to silicon components for semiconductor substrate processing systems, and more particularly to silicon components formed by electron beam melting.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to treat substrates such as semiconductor wafers. Examples of processes that may be performed on a substrate include, but are not limited to, chemical vapor deposition (CVD), atomic layer deposition (ALD), conductor etch, dielectric etch, rapid thermal processing (RTP), ion implant, physical vapor deposition (PVD), and/or other etch, deposition, or cleaning processes. A substrate may be arranged on a substrate support, such as a pedestal, an electrostatic chuck (ESC), etc. in a processing chamber of the substrate processing system. During processing, gas mixtures may be introduced into the processing chamber and plasma may be used to initiate and sustain chemical reactions.

The processing chamber includes various components including, but not limited to, the substrate support, a gas distribution device (e.g., a showerhead, which may also correspond to an upper electrode), a plasma confinement ring or shroud, etc. The substrate support may include a ceramic layer arranged to support a wafer. For example, the wafer may be clamped to the ceramic layer during processing. The substrate support may include an edge ring arranged around an outer portion (e.g., outside of and/or adjacent to a perimeter) of the substrate support. The edge ring may be provided to modify a plasma sheath above the substrate, optimize substrate edge processing performance, protect the substrate support from erosion caused by the plasma, etc. The plasma confinement shroud may be arranged around each of the substrate support and the showerhead to confine the plasma within the volume above the substrate.

### SUMMARY

A welded component for a substrate processing system includes a first component comprised of a first semiconductor material, a second component comprised of the first semiconductor material, a weld region defined between respective unwelded regions of the first component and the second component located on either side of the weld region, and a seam defined in the weld region between the first component and the second component. The weld region is comprised of the first semiconductor material of respective portions of the first component and the second component on either side of the seam that was melted and recrystallized to form the weld region.

In other features, the welded component is comprised of at least one of silicon and silicon carbide. The welded component is comprised of doped silicon. The welded component does not include any seams between the weld region and the respective unwelded regions of the first component and the second component. The weld region includes only a single seam between the first component and the second component.

In other features, the respective unwelded regions of the first component and the second component and the weld region each have a first crystalline structure. The respective unwelded regions have at least one of a different grain orientation, different grain sizes, and different grain boundaries relative to the weld region. An average grain size in the weld region is smaller than an average grain size in the respective unwelded regions.

In other features, the first semiconductor material is comprised of doped silicon, and wherein a distribution of dopant in the weld region is different from a distribution of the dopant in the respective unwelded regions. A concentration of the dopant in the weld region increases as a distance from the seam decreases such that the concentration of the dopant in the weld region is greater near the seam than near the unwelded regions. A distribution of the dopant in the respective unwelded regions is generally uniform and the distribution of the dopant in the weld region is nonuniform. The welded component is one of a plasma confinement ring, an edge ring, and an electrode of the substrate processing system.

A method of forming a welded component for a substrate processing system includes arranging a first component comprised of a first semiconductor material and a second component comprised of the first semiconductor material such that respective mating surfaces of the first component and the second component are in contact with each other, using an electron beam generator, heating the first component and the second component to a first temperature for a first period while rotating the first component and the second component at a first rate, and, subsequent to the first period, heating a joint between the first component and the second component to a second temperature greater than the first temperature while rotating the first component and the second component at a second rate less than the first rate to form the welded component comprising the first component, the second component, and a seam between the first component and the second component. The welded component includes a weld region defined around the seam and between respective unwelded regions of the first component and the second component located on either side of the weld region.

In other features, the welded component is one of a plasma confinement ring, an edge ring, and an electrode of the substrate processing system. The welded component is comprised of at least one of silicon, doped silicon, and silicon carbide. The respective unwelded regions of the first component and the second component and the weld region each have a first crystalline structure. The first semiconductor material is comprised of doped silicon, and wherein a distribution of dopant in the weld region is different from a distribution of the dopant in the respective unwelded regions.

In other features, the method further includes arranging the first component and the second component on a pedestal within a thermal chamber comprised of a plurality of layers of thermal insulative material. The method further includes, subsequent to forming the welded component, controlling the electron beam generator to anneal the welded component at a third temperature that is less than the second temperature and to cool the welded component at a controlled rate.

A welding system configured to weld a component of a substrate processing system includes a welding chamber, an electron beam generator mounted on a sidewall of the welding chamber, a temperature sensor, a pedestal configured to support the component within the welding chamber, a thermal chamber configured to be arranged to surround the pedestal and the component supported on the pedestal within the welding chamber, the pedestal being configured to rotate the component within the thermal chamber, and at least one opening in a sidewall of the thermal chamber aligned with the electron beam generator. The electron beam generator is configured to direct an electron beam at a joint between first and second portions of the component to weld the first portion to the second portion while the pedestal rotates the component.

In other features, the welding system further includes a laser mounted on a sidewall of the welding chamber configured to heat the component to a temperature above a brittle-to-ductile temperature of the component. The welding system further includes an external heater configured to heat the component to a temperature above a brittle-to-ductile temperature of the component.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example confinement ring or shroud for a substrate processing chamber;

FIG. 2A is an image of an example welded silicon component according to the present disclosure;

FIG. 2B is an illustration of an example welded silicon component according to the present disclosure;

FIGS. 3A-3C are example welding systems according to the present disclosure; and

FIG. 4 illustrates steps of an example method for welding silicon components according to the present disclosure.

In the drawings, reference numbers may be reused to identify similar and/or identical elements.

### DETAILED DESCRIPTION

Processing chambers for substrate processing systems may include one or more large (e.g., 100 mm diameter or greater) silicon (Si) or silicon carbide (SiC) components such as confinement rings or shrouds, edge rings, and upper electrodes. The large sizes of these components complicate manufacture. Some components may include shapes or features that further complicate manufacture. For example, an electrode configured as a showerhead may include one or more gas plenums and through holes for flowing gases through the electrode and into the processing chamber, which makes subtractive manufacturing methods (e.g., etching, machining, etc.) difficult or impossible. In other examples, subtractive methods cause large amounts of material to be removed. For example, confinement shrouds are substantially hollow, which requires removal (and waste) of a large amount of material.

When subtractive manufacturing methods are not possible, larger Si components may be assembled from multiple smaller components fastened together (e.g., using screws or other fasteners). In other examples, components may be bonded or fused together using, for example, a bonding material such as an elastomer. However, such bonds may have relatively weak tensile strength, limit a working temperature of the component, alter operating characteristics of the component (e.g., resistivity and thermal conductivity), and increase particle generation.

In other examples, liquid phase bonding may be used to bond two components using a bonding agent such as aluminum or gold heated above its melting temperature. However, a maximum application temperature is limited by a eutectic temperature of Si and the bonding agent. Further, the bonding agent may increase metallic contamination and generate non-volatile particles during subsequent use in substrate processing systems. In addition to contamination risk, coefficient of thermal expansion (CTE) between Si and the bond materials is typically different which can cause shear stress in Si and weaken mechanical strength.

In still other examples, Si material adjacent to a seam between two components is heated such that the Si material melts and flows into the seam, functioning as a bond material. However, in these examples multiple seams are created: a first seam between a first component and the bond material and a second seam between a second component and the bond material.

Si components according to the principles of the present disclosure include two or more components welded directly together. In other words, components are welded together without a bonding material or agent and without external surface Si melted and flowed into a gap between the components. Accordingly, a welded joint between Si components according to the present disclosure includes only a single seam. As one example, the components are welded together using electron beam melting (EBM) as described below in more detail.

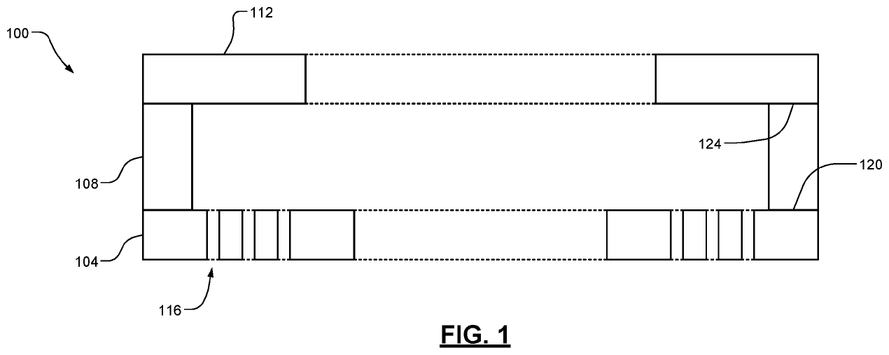

FIG. 1 shows an example confinement ring or shroud 100 (referred to herein as a confinement ring) for a substrate processing chamber. In some examples, plasma confinement rings are C-shaped in cross-section (as shown). For example, the confinement ring includes a lower portion (a lower disc or ring 104), a cylindrical middle portion 108, and an upper portion (an upper disc or ring) 112. The lower portion 104, the middle portion 108, and the upper portion 112 are annular. Slots or holes 116 may be defined in the lower portion 104 to vent gases out of a plasma confinement region within the confinement ring 100. In some examples, an L-shaped confinement ring or shroud may be used instead of C-shaped plasma confinement rings. In L-shaped confinement rings, the upper portion 112 may be omitted.

The lower portion 104, the middle portion 108, and the upper portion 112 of the confinement ring 100 are welded together as described below in more detail. Specifically, the lower portion 104, the middle portion 108, and the upper portion 112 are welded together without a bonding material or agent and without external surface Si melted and flowed into a gap between the components. Accordingly, each of a welded joint 120 between the lower portion 104 and the middle portion 108 and a welded joint 124 between the middle portion 108 and the upper portion 112 according to the present disclosure includes only a single seam. As one example, the lower portion 104, the middle portion 108, and the upper portion 112 are welded together using electron beam melting (EBM) to form the welded joints 120, 124.

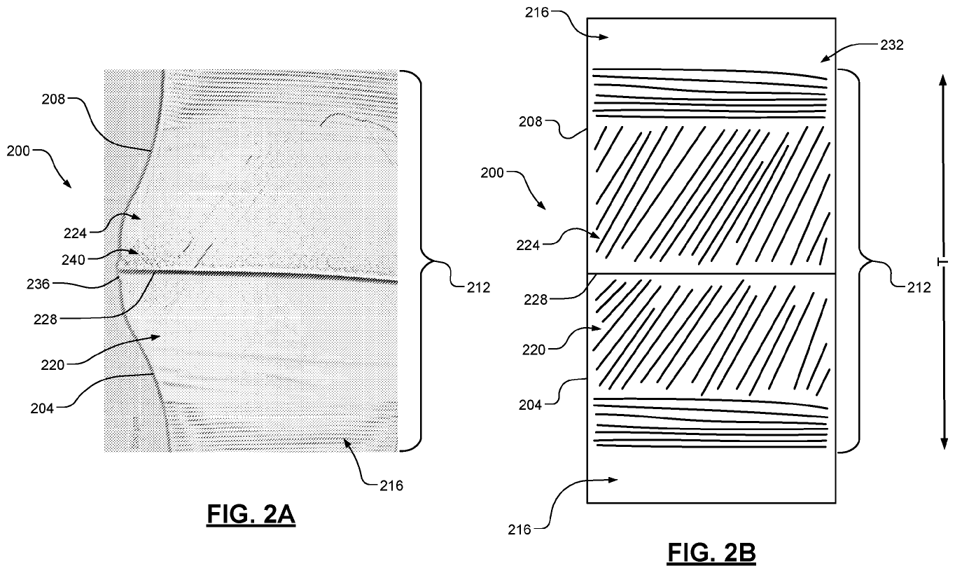

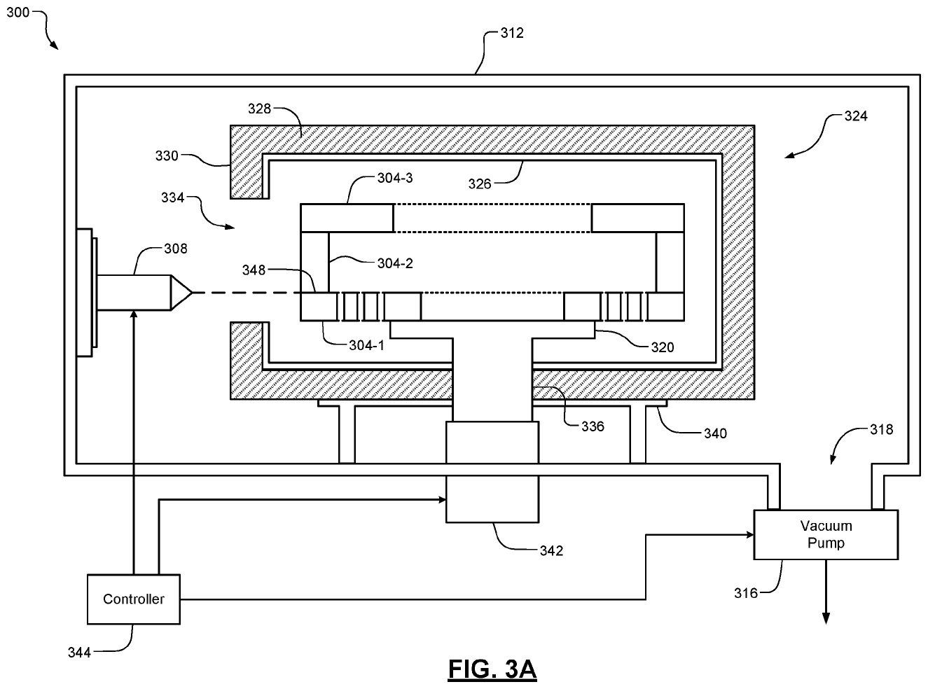

FIGS. 2A and 2B show a cross-section of a joint of an example welded silicon component 200. The welded silicon component 200 includes a first component 204 and a second component 208 welded together according to the principles of the present disclosure. FIG. 2A shows a magnified captured image of the welded silicon component 200 and FIG. 2B is an example illustration of the welded silicon component 200. For example only, the first and second components 204, 208 correspond to different portions of the confinement ring 100 shown in FIG. 1.

The welded silicon component 200 includes observable structural differences between a weld region 212 and unwelded regions 216 (not shown in FIG. 2A). The weld region 212 includes respective melted and recrystallized regions 220, 224 of the first and second components 204, 208 and a seam 228. The unwelded regions 216 correspond to the original silicon of the first and second components 204, 208. In other words, the unwelded regions 216 are not melted and recrystallized during a welding process and therefore comprise the original crystalline structure of the silicon prior to welding.

Accordingly, a crystal structure of the silicon in the weld region 212 is similar to the crystal structure of the silicon in the unwelded regions 216 but with observable differences. However, a boundary may be observed in a transitional region 232 between the weld region 212 and the unwelded regions 216. For example, differences between the weld region 212 and the unwelded regions 216 include, but are not limited to, grain boundaries between the weld region 212 and the unwelded regions 216 and an increase in dislocations. Therefore, in some examples, grain sizes (e.g., an average grain size) are smaller in the weld region 212 than the unwelded regions 216. For example only, grain size may be measured in a direction parallel to a growth direction (i.e., as a longest distance between adjacent boundaries of a grain). Grain size may be measured using a low magnification light microscope, a photo-imaging system, etc.

In other words, while the crystal structures of the weld region 212 and the unwelded regions 216 are substantially the same, differences in crystal orientation between the weld region 212 and the unwelded regions 216 cause lattice mismatches observable as a grain boundary. The weld region 212 is shown with diagonal lines and horizontal lines illustrating slip and striation, respectively. However, these lines are provided only to illustrate that the silicon in the weld region 212 has observable characteristics caused by growth fluctuation and thermal stress during welding, which may not be present in the unwelded regions 216, and are not intended to exactly represent or limit the crystal structures in these regions.

The weld region 212 may include one or more structural elements that are observable from an exterior of the welded silicon component 200. In some examples, a sidewall 236 of the welded silicon component 200 may protrude outward on either side of an outer edge of the seam 228 as shown in FIG. 2A. In other examples, dislocations (e.g., etch pits) 240 may be observable at the outer edge of the seam 228.

In some examples, the welded silicon component 200 is comprised of doped silicon. For example, a dopant having a high segregation coefficient such as boron (e.g., a segregation coefficient of 0.7) is used to provide consistent resistivity throughout the welded silicon component 200. A distribution of the dopant is typically relatively uniform throughout the body of the welded silicon component 200 (i.e., throughout the unwelded regions 216). However, melting the doped silicon to weld the first and second components 204, 208 together according to the principles of the present disclosure causes redistribution of the dopant in the weld region 212.

For example, the dopant has a greater concentration at the seam 228 than in other portions of the weld region 212 and in the unwelded regions 216. In other words, a concentration of the dopant decreases as a distance from the seam 228 increases (or increases as a distance from the seam 228 decreases). In other examples, redistribution of the dopant causes a different distribution pattern of the dopant within the weld region 212 or portions of the weld region 212.

A thickness (e.g., a thickness T) of the weld region 212 may vary in accordance with a length of the seam 228. In other words, the thickness T varies in accordance with a width of the components being welded together and the resulting weld region. For example, the length of the seam 228 determines a duration of the weld process (as described below in more detail), which in turn determines an amount of silicon material melted and recrystallized during the weld process. Accordingly, as the length of the seam 228 increases, the thickness T also increases. As one example, the thickness T is between 1.0 and 5.0 mm.

As described above, the welded silicon component 200 according to the present disclosure includes the first and second components 204, 208 welded directly together without a bonding material or agent and without external surface silicon melted and flowed into the seam 228. Accordingly, the weld region 212 between the first and second components 204, 208 includes only the single seam 228. The welded silicon component 200 includes unwelded regions 216 comprising silicon characterized by a first (e.g., unwelded/unmelted) crystalline structure and a weld region 212 comprising silicon characterized by a second (e.g., melted and recrystallized) crystalline structure.

As one example, the components are welded together using electron beam melting (EBM). EBM systems are typically configured for welding ductile materials that are tolerant to thermal stress (e.g., metal materials). Conventional EBM systems are not configured to uniformly heat non-metal substrates (e.g., at temperatures greater than 600° C.). Accordingly, significant temperature gradients occur while welding large, nonmetal components. EBM systems are especially unsuitable for welding silicon components, which require much larger temperatures (e.g., greater than 1400° C.) for welding. Further, cooldown subsequent to welding is not controlled. Temperature gradients during welding and cooling can cause cracks and other defects.

In some examples, EBM systems use external resistive or induction heaters and thermal insulation to reduce heat loss. External heaters increase the overall size of the system and introduce other design complications.

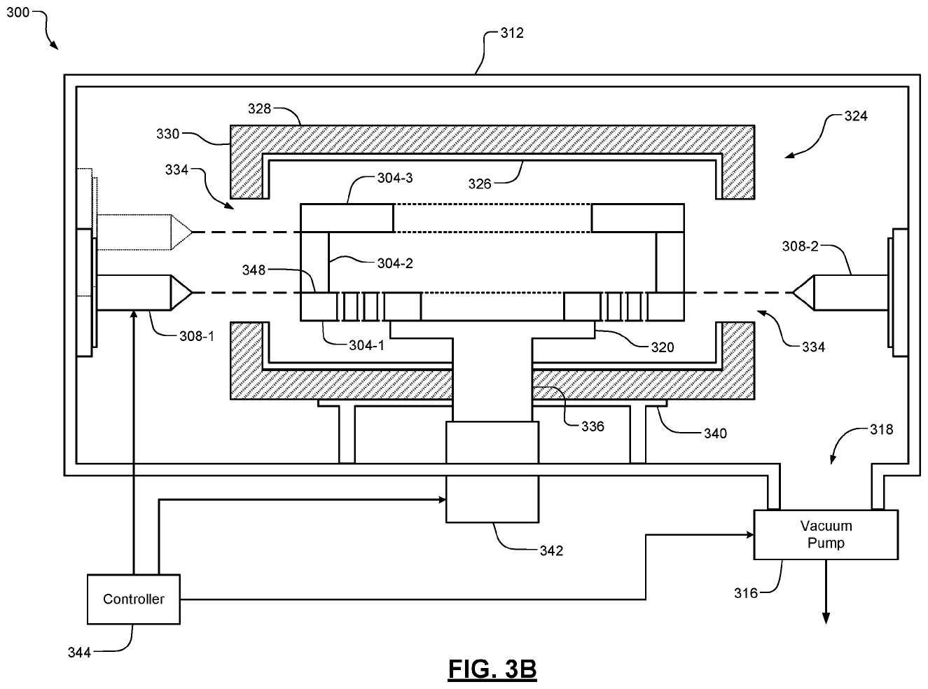

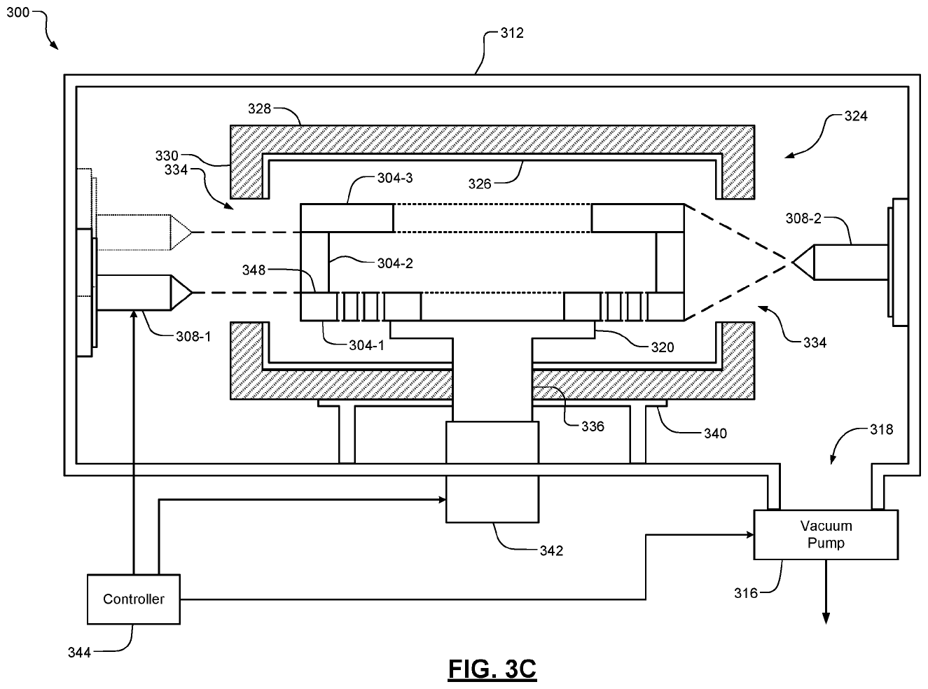

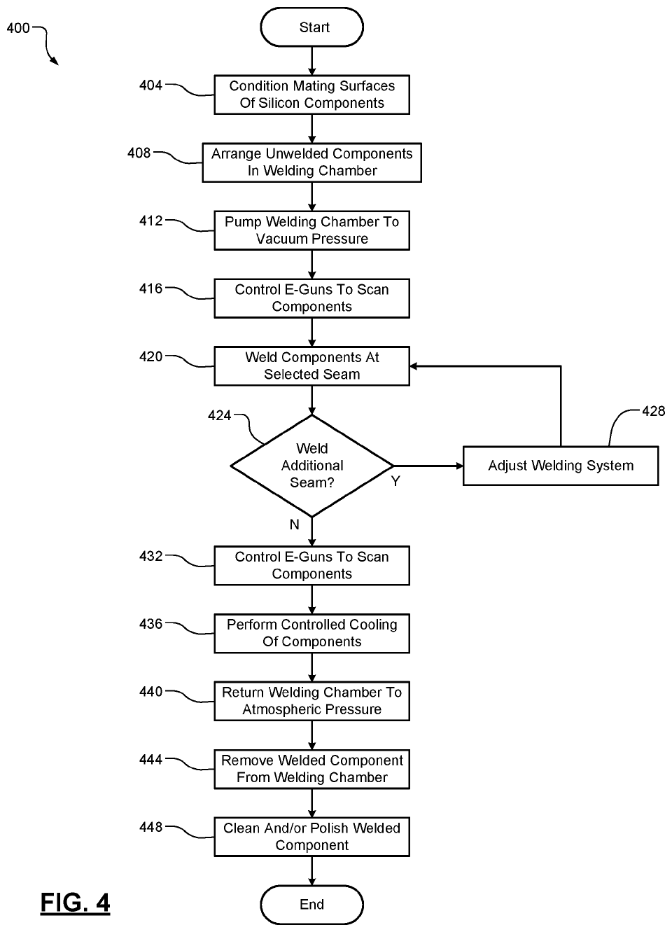

An example EBM welding system 300 according to the present disclosure is shown in FIGS. 3A, 3B, and 3C. The welding system 300 is configured to weld multiple silicon components into a single silicon component (e.g., components 304-1, 304-2, and 304-3, collectively referred to as components 304, corresponding to a confinement shroud) using one or more electron beam generators, such as electron guns (E-guns) 308. The welding system 300 is configured to uniformly heat target portions of the components and minimize temperature gradients during heating and welding, annealing, and controlled cooling to eliminate cracking and other defects without using external heaters. Accordingly, the design of the welding system 300 is simplified and cost and energy consumption are reduced. Although not shown, in some examples the welding system 300 may additionally include an external heater (e.g., a graphite resistive heater) configured to heat (e.g., pre-heat, prior to welding) the components 304 to a temperature above a brittle-to-ductile temperature of the components 304. Although described herein as electron guns, other heating devices may be used (e.g., a laser or other radiation beam device).

The welding system 300 includes a welding chamber 312. The welding chamber 312 may be maintained at a predetermined pressure. In some examples, the welding chamber 312 is maintained at vacuum (e.g., using a vacuum pump 316 configured to pump down the welding chamber 312 via a port 318). The E-guns 308 are mounted on an interior sidewall of the welding chamber 312. As shown in FIG. 3A, the welding system 300 includes a single E-gun 308. As shown in FIGS. 3B and 3C, the welding system includes two E-guns 308-1 and 308-2 (collectively, E-guns 308). In other examples, more E-guns may be used. In some examples, the welding system 300 may include other heating elements (not shown), such as a laser mounted on a sidewall of the welding chamber 312 configured to heat (e.g., pre-heat, prior to welding) the components 304 to a temperature above a brittle-to-ductile temperature of the components 304.

The components 304 are arranged on a pedestal 320 (e.g., a graphite pedestal) within an insulative thermal chamber 324. For example, the thermal chamber 324 is comprised of one or more layers of insulative materials. As one example, the thermal chamber 324 includes an inner layer 326 (e.g., a graphite liner), a middle layer 328 (e.g., a molybdenum layer), and an outer layer 330 (e.g., a soft carbon fiber felt layer). In other examples, the thermal chamber 324 may be comprised of other combinations of layers including graphite, molybdenum, rigid carbon fiber, soft carbon fiber felt, carbon composite, etc. To minimize particle shedding, high density graphite or molybdenum are used for the inner layer 326.

The thermal chamber 324 surrounds the components 304 and the pedestal 320 to facilitate control of uniform heating and cooling. The thermal chamber 324 includes one or more openings 334 to allow electron beams generated by the E-guns 308 to pass through sidewall of the thermal chamber 324 and heat target regions of the components 304. For example, the number of the openings 334 corresponds to the number of E-guns 308 used. More than one E-gun may be used if a single E-gun is not sufficient to achieve desired power and/or temperature uniformity. The number of E-guns 308 used may be dependent upon factors including, but not limited to, a quantity and sizes of the components 304 and insulative properties of the thermal chamber 324. If more than one E-gun 308 is used, the E-guns 308 and openings 334 may be evenly (i.e., symmetrically) spaced around the welding chamber 312 to facilitate uniform temperature control.

The thermal chamber 324 further includes an opening 336 for the pedestal 320. For example, the thermal chamber 324 is supported on a platform 340 and the pedestal 320 passes through the platform 340 and the opening 336 into the thermal chamber 324. The pedestal 320 is coupled to a spindle 342. The spindle 342 is configured to rotate at a controlled rate (e.g., response to control signals from a controller 344) during welding. Accordingly, the E-guns 308 are directed at a target region of the components 304 (e.g., one or more seams 348 between adjacent components) and the pedestal 320 is rotated to expose the entire seam 348 (i.e., around an entire outer perimeter/circumference of the components 304) to the electron beam. In some examples, one or more of the pedestal 320 and the E-guns 308 may be configured to be raised and lowered (e.g., responsive to control signals from the controller 344) to align the E-guns with the target region of the components 304. The controller 344 may also be configured to control operation of the E-guns 308 and the vacuum pump 316.

As shown in FIG. 3B, both E-guns 308 may be used for welding. As shown in FIG. 3C, the E-gun 308-1 may be used for welding while the E-gun 308-2 is used for heating/scanning the components 304 during and/or subsequent to welding. In other examples, the same E-gun used for welding (e.g., the E-gun 308-1) may also be configured to perform scanning. As used herein, “scanning” refers to applying the electron beam at a lower heat or intensity than an intensity used for welding and annealing the components, maintain uniform temperatures to minimize temperature gradients across the components, and control cooling. The E-gun 308-2 may be configured to generate an electron beam having a larger contact area than the electron beam of the E-gun 308-1. Accordingly, the opening 334 for the E-gun 308-2 may be larger than the opening 334 for the E-gun 308-1.

For example, subsequent to welding, the E-gun 308-2 may be used to anneal the components 304 at a relatively lower temperature (e.g., 900-1300° C.) for a predetermined period (e.g., one hour) while the pedestal 320 is rotating at a rate greater than a rotation rate used during welding. For example, during scanning, the pedestal 320 may be rotated at eight or more rotations per minute (RPM). The components 304 can then be allowed to slowly cool in a controlled manner by gradually reducing the scanning temperature. In one example, the components 304 are first cooled by reducing the temperature by 1-5° C. per minute until the temperature reaches a first cooled temperature (e.g., 600-800° C.). The components 304 may then be allowed to cool more rapidly by ending the scanning (i.e., by powering of the E-gun 308-2).

FIG. 4 illustrates an example method 400 for welding silicon components according to the present disclosure. For example, the method 400 is performed using the welding system 300 described above in FIGS. 3A-3C, including steps performed in response to control signals generated by a controller such as the controller 344. In one example, the controller 344 corresponds to a processor configured to execute code, stored in memory, that includes instructions for operating the E-guns 308, the vacuum pump 316, the pedestal 320, and/or other components of the welding system 300.

At 404, mating surfaces of silicon components to be welded together may optionally be conditioned (e.g., polished and/or cleaned, etched, etc.) to facilitate welding. At 408, the unwelded components are arranged in a welding chamber 312 (e.g., arranged on the pedestal 320). For example, unwelded components are arranged such that mating surfaces of the unwelded components are in contact with each other. In some examples, the components are assembled on the pedestal 320 without any portion of the thermal chamber 324 present within the welding chamber 312 and the thermal chamber 324 is subsequently assembled/installed around the pedestal 320. In other examples, the thermal chamber 324 may include a removable lid or opening and the components may be arranged on the pedestal 320 through the opening.

Arranging the unwelded components on the pedestal 320 may optionally include adjusting positions (e.g., vertical positions) of the components, the pedestal 320, and/or the E-guns 308 to align the E-guns 308 with the target regions (i.e., the seams 348) of the components. For example, the pedestal 320 and/or the E-guns 308 may be configured to be raised and lowered. For example, as shown in FIGS. 3B and 3B, one or both of the E-guns 308 can be raised to align with a seam between the components 304-2 and 304-3. In other examples, the welding system 300 may be configured for specific components and adjustment is not required.

At 412, the welding chamber 312 is pumped to a desired pressure (e.g., vacuum pressure less than or equal to 10⁻⁵ torr). At 416, the one or more E-guns 308 are controlled to scan (i.e., heat) the components to a scanning temperature while rotating the pedestal 320 at a first (“high”) rate, such as a rate greater than or equal to eight RPM. For example, the scanning temperature is a temperature at which the material of the components (e.g., doped silicon) transitions from brittle to ductile. As one example, the first temperature is greater than 1000° C.

At 420, subsequent to a predetermined first scanning period (e.g., one hour) or a determination that the temperature of the components is greater than or equal to the first temperature, one or more of the E-guns 308 are controlled to focus an electron beam at a first selected joint or seam while the pedestal 320 is rotated at a second rate (e.g., less than eight RPM) to weld the components together. For example, at 420, the intensity of the electron beam is increased relative to the intensity of the electron beam used for scanning at 416. As one example, a seam closest to the pedestal 320 is welded first.

The second rate of rotation and a duration of the welding performed at 420 varies based on factors such as intensity of the electron beam, a thickness or width of the seam, a temperature within the thermal chamber 324, size and dimensions (e.g., overall radius) of the components, a number of the E-guns 308 used for welding, etc. In this example, the welding is performed for a predetermined welding period and the method 400 then continues to 424.

At 424, the method 400 determines whether to weld additional seams of the components. If true, the method 400 continues to 428. If false, the method 400 continues to 432. At 428, one or more components of the welding system 300 are adjusted to direct the electron beam at another seam of the components (e.g., a next-closest seam to the pedestal 320). To re-direct the electron beam, the pedestal 320 and/or the E-gun 308 may be raised or lowered and/or an output angle of the E-gun 308 may be adjusted. The method 400 then continues to 420 to weld the next seam of the components.

At 432, the one or more E-guns 308 are controlled to scan the components for a second scanning period (e.g., while rotating the pedestal 320 at the first rate. During the second scanning period, the components may be maintained at the scanning temperature for a predetermined period (e.g., one hour) to anneal the components. At 436, subsequent to the second scanning period, the components are cooled in a controlled manner. For example, the E-guns 308 are first controlled to allow the components to allow the temperature of the components to decrease at a rate of 1-5° C. per minute to a cooled temperature (e.g., 600-800° C.) and then turned off completely to allow the components to continue to cool. For example only, the cooled temperature is a temperature at which subsequent cooling of the components is unlikely to cause cracking or other defects.

At 440, the welding chamber 312 is returned to atmospheric pressure. In one example, the welding chamber 312 is pumped with an inert gas or gas mixture (e.g., argon) to atmospheric pressure. At 444, the welding chamber 312 is opened and the welded component is removed. At 448, the welded component is optionally cleaned and polished. For example, excess silicon may be grinded from the welded component (e.g., at outer edges of the seam 348).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1-12. (canceled)

13. A method of forming a welded component for a substrate processing system, the method comprising:
arranging a first component comprised of a first semiconductor material and a second component comprised of the first semiconductor material such that respective mating surfaces of the first component and the second component are in contact with each other;
using at least one electron beam generator, heating the first component and the second component to a first temperature for a first period while rotating the first component and the second component at a first rate; and
subsequent to the first period, heating a joint between the first component and the second component to a second temperature greater than the first temperature while rotating the first component and the second component at a second rate less than the first rate to form the welded component comprising the first component, the second component, and a seam between the first component and the second component,
wherein the welded component comprises a weld region defined around the seam and between respective unwelded regions of the first component and the second component located on either side of the weld region.

14. The method of claim 13, wherein the welded component is one of a plasma confinement ring, an edge ring, and an electrode of the substrate processing system.

15. The method of claim 13, wherein the welded component is comprised of at least one of silicon, doped silicon, and silicon carbide.

16. The method of claim 13, wherein the respective unwelded regions of the first component and the second component and the weld region each have a first crystalline structure.

17. The method of claim 13, wherein the first semiconductor material is comprised of doped silicon, and wherein a distribution of dopant in the weld region is different from a distribution of the dopant in the respective unwelded regions.

18. The method of claim 13, further comprising arranging the first component and the second component on a pedestal within a thermal chamber comprised of a plurality of layers of thermal insulative material.

19. The method of claim 13, further comprising, subsequent to forming the welded component, controlling the at least one electron beam generator to anneal the welded component at a third temperature that is less than the second temperature and to cool the welded component at a controlled rate.

20. A welding system configured to weld a component of a substrate processing system, the welding system comprising:
a welding chamber;
at least one electron beam generator mounted on a sidewall of the welding chamber;
a temperature sensor;
a pedestal configured to support the component within the welding chamber;
a thermal chamber configured to be arranged to surround (i) the pedestal and (ii) the component supported on the pedestal within the welding chamber, wherein the pedestal is configured to rotate the component within the thermal chamber; and
at least one opening in a sidewall of the thermal chamber aligned with the electron beam generator,
wherein the at least one electron beam generator is configured to preheat first and second portions of the component, and subsequent to preheating the first and second portions, to direct at least one electron beam at a joint between the first and second portions of the component to weld the first portion to the second portion while the pedestal rotates the component.

21. The welding system of claim 20, further comprising a laser mounted on a sidewall of the welding chamber configured to heat the component to a temperature above a brittle-to-ductile temperature of the component.

22. The welding system of claim 20, further comprising an external heater configured to heat the component to a temperature above a brittle-to-ductile temperature of the component.

23. The method of claim 13, wherein the at least one electron beam generator is configured, subsequent to the first period, to heat the joint between the first component and the second component to the second temperature.

24. The method of claim 13, wherein the at least one electron beam generator comprises a plurality of electron beam generators configured to
heat the first component and the second component to the first temperature for the first period; and
subsequent to the first period, heat the joint between the first component and the second component to the second temperature while the first component and the second component are rotated at the second rate to form the welded component.

25. The method of claim 13, wherein the at least one electron beam generator comprises:
a first electron beam generator configured to heat the first component and the second component to the first temperature for the first period; and
a second electron beam generator configured, subsequent to the first period, to heat the joint between the first component and the second component to the second temperature while the first component and the second component are rotated at the second rate to form the welded component.

26. The welding system of claim 20, wherein the at least one electron beam generator comprises a plurality of electron beam generators configured to:
preheat the first and second portions of the component to a first temperature for a first period; and
subsequent to the first period, heat the joint between the first and second portions of the component to a second temperature while rotating the component to weld the first and second portions.

27. The welding system of claim 20, wherein the at least one electron beam generator comprises:
a first electron beam generator configured to heat the first and second portions of the component to a first temperature for a first period; and
a second electron beam generator configured, subsequent to the first period, to heat the joint between the first and second portions to a second temperature while the component is rotated to weld the first and second portions of the component.
